(19) United States
(12) Patent Application Publication
(10) Pub. No.: US 2008/0293182 A1
(43) Pub. Date: Nov. 27, 2008

(54) Method for Manufacturing Image Sensor

(76) Inventors: Yong Sil Lee, Cheongwon-gun (KR); Jun Sung Oh, Suwon-si (KR); Seung Young Jeong, Osan-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/125,635

(22) Filed: May 22, 2008

(30) Foreign Application Priority Data
May 25, 2007 (KR) 10-2007-0050617

(51) Int. Cl. H01L 31/0232

(52) U.S. Cl. 438/70; 257/E31.127

(57) ABSTRACT

Disclosed are methods of manufacturing an image sensor. The method can include forming a microlens by depositing photoresist bubbles on a substrate. The photoresist bubbles can be formed and deposited using an inkjet scheme. A curing process of the photoresist can be performed during formation of the photoresist bubbles before the photoresist bubbles are deposited on the substrate. In one embodiment, the photoresist bubbles can be color photoresist bubbles to form a color microlens that can function as a color filter and a microlens.

### CROSS-REFERENCE TO RELATED APPLICATION

The present application claims the benefit under 35 U.S.C. §119 of Korean Patent Application No. 10-2007-0050617, filed May 25, 2007, which is hereby incorporated by reference in its entirety.

### BACKGROUND

According to a related art, a microlens photo process is performed by using a special photoresist used to form a microlens and then performing a reflowing process relative to the special photoresist to form the microlens of an image sensor.

However, according to the related art, a gap may be formed between the microlenses during the reflow process of the photoresist, so that an amount of light incident into a photodiode is reduced, causing defect of an image.

In addition, when a microlens including an organic substance is manufactured through the related art, particles can be generated when a wafer is sawn in a subsequent process, such as a packaging process or a bumping process of a semiconductor chip mounting process. The particles may collide with the microlens or adhere to the microlens, thereby causing defect of an image.

In addition, according to the related art, the margin of the microlens may be insufficient and curvature of the lens may be very small, so that the microlens cannot effectively collect the light.

### BRIEF SUMMARY

Embodiments of the present invention provide a method of manufacturing an image sensor, and in particular, a method of fabricating a microlens. Embodiments of the subject method are capable of minimizing a gap between microlenses.

An embodiment of the present invention also provides a method of manufacturing an image sensor capable of improving a curvature of a microlens.

According to embodiments, the manufacturing process for a microlens can be simplified while enabling mass-production of the microlenses.

In one embodiment, the method can include forming an interlayer dielectric layer on a substrate; forming a color filter on the interlayer dielectric layer; and forming photoresist bubbles on the color filter to form a microlens.

In another embodiment, the method can include: forming an interlayer dielectric layer on a substrate; and forming color photoresist bubbles on the interlayer dielectric layer to form a color microlens.

### BRIEF DESCRIPTION OF THE DRAWINGS

FIGS. 1 to 3 are cross-sectional views showing a method of manufacturing an image sensor according to an embodiment of the present invention.

FIGS. 4 and 5 are cross-sectional views showing a method of manufacturing an image sensor according to an embodiment of the present invention.

### DETAILED DESCRIPTION

Hereinafter, a method of manufacturing an image sensor according to the embodiments will be described with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

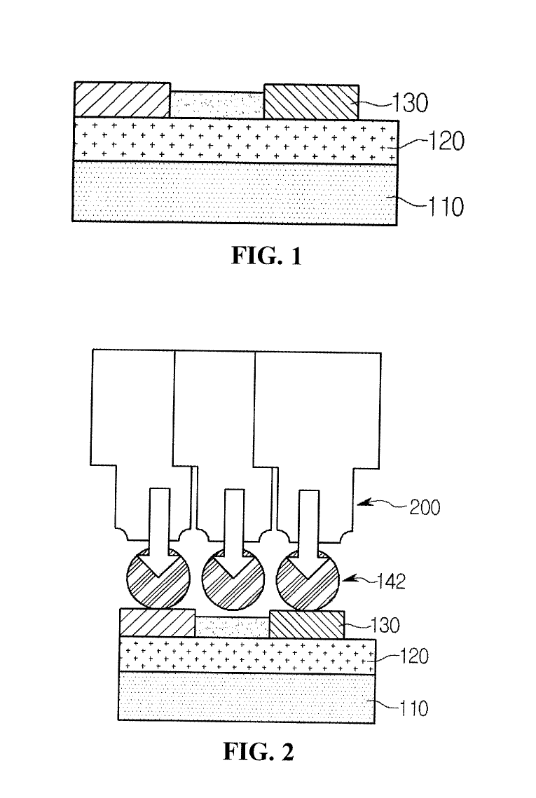

FIGS. 1 to 3 are cross-sectional views for describing a method of manufacturing an image sensor according to a first embodiment.

Referring to FIG. 1, an interlayer dielectric layer 120 can be formed on a substrate 110.

In one embodiment, the substrate 110 can include a photodiode (not shown). In a further embodiment, other structures can be provided on the substrate below the interlayer dielectric layer 120.

In an embodiment, the interlayer dielectric layer 120 can have a multi-layer structure, in which a light blocking layer (not shown) is formed on a first interlayer dielectric layer to block light being incident into an undesired region and a second interlayer dielectric layer is provided on the light blocking layer.

A protective layer (not shown) can be formed on the interlayer dielectric layer 120 to protect devices from moisture or scratch.

Then, after coating the interlayer dielectric layer 120 with dyeable photoresist, an exposure and development process can be performed to form a color filter 130. The color filter 130 can include red (R), green (G), and blue (B) filters for filtering light according to wavelengths of the light.

A planarization layer (not shown) can be formed on the color filter 130 to ensure flatness of the color filter 130, and to adjust the focal length of a lens layer formed on the color filter 130.

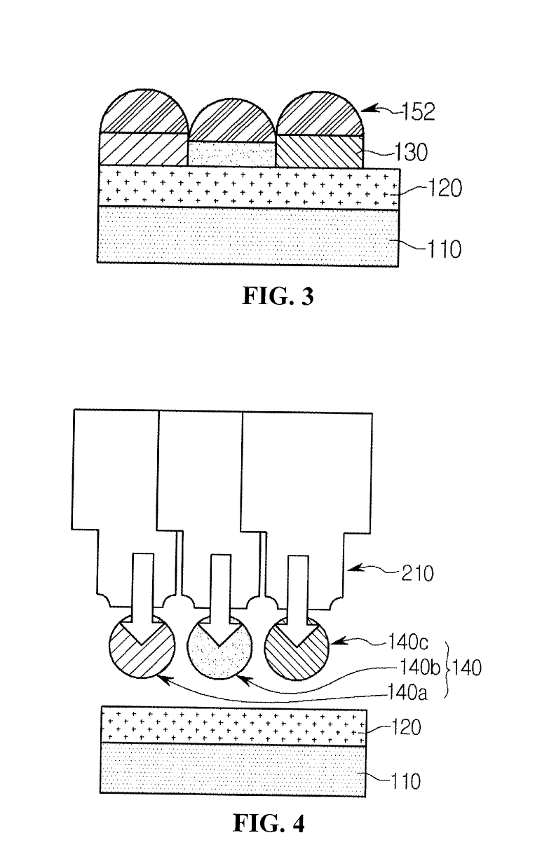

Then, referring to FIGS. 2 and 3, a photoresist bubble 142 can be formed on the color filter layer 130, thereby forming a microlens 152. Although the figures show microlenses 152 at varying heights due to varying height of the color filter 130, this should not be construed as a limitation on the planarity of the microlenses 152 or the color filter 130. For example, for embodiments incorporating a planarization layer, the microlenses 152 are formed on the planar surface of the planarization layer above the color filter 130. In addition, certain embodiments can incorporate color filters 130 having a planar top surface. For such embodiments, the lower surfaces of the color filter 130 may be at different depths.

In contrast to the related art, according to the first embodiment, the photoresist bubble 142 can be produced through an inkjet scheme such that the microlens 152 can be formed on the color filter 130.

According to an embodiment, the microlens 152 can be obtained by forming the photoresist bubble 142 on the color filter 130 using an inkjet printer 200.

The inkjet printer 200 employed in the first embodiment can be an apparatus for printing an image having a predetermined color by exhausting fine photoresist droplets onto a desired position of a recording medium.

The inkjet printer 200 can be classified into an electro-thermal transducer type inkjet printer and an electro-mechanical transducer type inkjet printer. The electro-thermal transducer type inkjet printer generates photoresist bubbles by applying heat to a photoresist such that the photoresist can be exhausted to an exterior. The electro-mechanical transducer type inkjet printer exhausts the photoresist by varying the volume of the photoresist using a piezoelectric member.

In detail, according to the electro-thermal transducer type inkjet printer, when power is applied to a heater including heating elements, a portion of the photoresist near the heater is heated up to a temperature of, for example, 300° C. At this time, bubbles are produced in the photoresist by the heat. The bubbles are grown when the volume of the photoresist expands to apply pressure to the chamber filled up with the photoresist. Thus, the photoresist nearest to a nozzle is exhausted out of the chamber through the nozzle in the form of a photoresist bubble, or droplet.

In one embodiment, the electro-thermal transducer type inkjet printer can have a top-shooting scheme. According to the top-shooting scheme, the growing direction of bubbles is identical to the exhaust direction of the photoresist droplets.

In another embodiment, the electro-thermal transducer type inkjet printer can have a back-shooting scheme. According to the back-shooting scheme, the growing direction of bubbles is opposite to the exhaust direction of the photoresist droplets.

According to the first embodiment, a curing process can be performed while the photoresist bubbles 142 are being generated in the photoresist by the inkjet printer 200. Therefore, an additional heat-treatment process, such as a microlens reflow process or baking process can be omitted. Furthermore, the curvature of the microlens 152 can be improved and the light focusing performance of the microlens 152 can be remarkably improved by omitting the reflow or baking process.

In addition, since the curing process can be performed while the photoresist bubbles 142 are being generated in the inkjet printer, a bridge phenomenon can be inhibited from occurring between the microlenses 152. Accordingly, the size of a gap formed between the microlenses 152 can be reduced.

Further, since the curing process can be performed while the photoresist bubbles 142 are being generated and the bridge phenomenon can be inhibited, a sufficient margin can be ensured during the microlens manufacturing process.

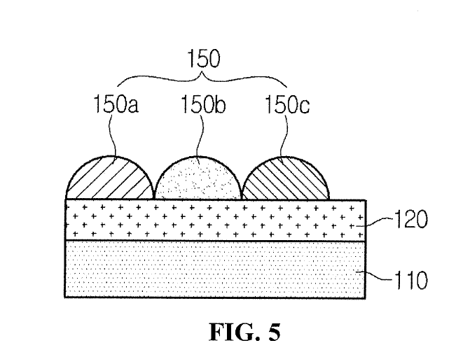

A method of manufacturing an image sensor according to a second embodiment will be described with reference to FIGS. 4 and 5.

According to the second embodiment, a microlens 150 is provided that can also function as a color filter.

Referring to FIG. 4, an interlayer dielectric layer 120 is formed on a substrate 110.

The substrate 110 can include a photodiode (not shown). In a further embodiment, a protective layer (not shown) can be formed on the interlayer dielectric layer 120.

Then, a color microlens 150 can be formed on the interlayer dielectric layer 120 through an inkjet scheme.

Referring to FIG. 4, the color microlens 150 can be obtained by forming color photoresist bubbles 140 on the interlayer dielectric layer 120.

In one embodiment, the color microlens 150 can be obtained by forming the color photoresist bubbles 140 on the interlayer dielectric layer 120 by using a color inkjet printer 210.

The color photoresist bubbles 140 can include a red bubble 140a, a green bubble 140b and a blue bubble 140c.

Accordingly, referring to FIG. 5, the color microlens 150 can include a red color microlens 150a, a green color microlens 150b, and a blue color microlens 150c.

According to the second embodiment, since the color microlens 150 can be formed by using a color (or dyed) photoresist, the process for forming the color filter can be omitted. Therefore, the manufacturing process can be simplified. In addition, the product yield can be improved and the precision of the manufacturing process can be improved.

Furthermore, according to the second embodiment, the curing process of the photoresist can be performed while the color photoresist bubbles 140 are being generated in by the color inkjet printer 210. Accordingly, an additional heat-treatment process, such as the reflow process and the baking process, can be omitted. Therefore, the curvature of the color microlens 150 can be improved and the light focusing performance of the color microlens 150 can be remarkably improved.

In addition, according to the second embodiment, since the curing process is performed while the photoresist bubbles 140 are being generated, a bridge phenomenon can be inhibited from occurring between the color microlenses 150. Therefore, the size of a gap formed between the color microlenses 150 can be reduced and a sufficient margin can be ensured during the microlens manufacturing process.

It will be apparent to those skilled in the art that various modifications and variations can be made in the present invention. Thus, it is intended that the present invention covers the modifications and variations thereof within the scope of the appended claims.

For instance, embodiments of the present invention can be applied to a CCD image sensor or a CMOS image sensor.

According embodiments of the present invention, the microlenses can be formed through an inkjet scheme. Therefore, certain embodiments can form microlenses where the size of the gap formed between the microlenses can be minimized.

In addition, according to an embodiment, since the microlenses can be formed through an inkjet scheme, the curing process of the photoresist is performed while the photoresist bubbles are being generated in the inkjet printer. Accordingly, the curvature of the microlens can be improved and the light focusing performance of the microlens can be improved.

Further, according to an embodiment, since the microlenses can be formed through an inkjet scheme, the manufacturing process for the microlenses can be simplified and the product yield of the microlens can be improved.

In addition, since the color microlens is formed by using a color photoresist, the process for forming the color filter can be omitted, so that the product yield can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing an image sensor, comprising:
forming an interlayer dielectric layer on a substrate;
forming a color filter on the interlayer dielectric layer; and
depositing photoresist bubbles on the color filter to form microlenses.

2. The method according to claim 1, wherein depositing the photoresist bubbles comprises using an inkjet scheme.

3. The method according to claim 1, wherein depositing the photoresist bubbles comprises using an inkjet printer.

4. The method according to claim 3, further comprising:
forming the photoresist bubbles using an electro-mechanical element of the inkjet printer.

5. The method according to claim 3, further comprising:
forming the photoresist bubbles using an electro-thermal mechanism of the inkjet printer.

6. The method according to claim 5, wherein the forming of the photoresist bubbles comprises:
heating a photoresist in a chamber of the inkjet printer such that pressure occurs in the chamber to expel photoresist droplets from a nozzle of the inkjet printer, the droplets providing the photoresist bubbles.

7. The method according to claim 3, further comprising performing a curing process in the inkjet printer before depositing the photoresist bubbles.

8. A method of manufacturing an image sensor, comprising:
forming an interlayer dielectric layer on a substrate; and
depositing color photoresist bubbles on the interlayer dielectric layer to form color microlenses.

9. The method according to claim 8, wherein the color photoresist comprises dyeable photoresist.

10. The method according to claim 8, wherein the color photoresist comprises red wavelength filtering photoresist, green wavelength filtering photoresist, and blue wavelength filtering photoresist.

11. The method according to claim 8, wherein depositing the color photoresist bubbles comprises using an inkjet scheme.

12. The method according to claim 8, wherein depositing the color photoresist bubbles comprises using an inkjet printer.

13. The method according to claim 12, wherein the inkjet printer is a color inkjet printer capable of depositing multiple colors of color photoresist bubbles.

14. The method according to claim 12, further comprising:
forming the color photoresist bubbles using an electro-mechanical element of the inkjet printer.

15. The method according to claim 12, further comprising:
forming the color photoresist bubbles using an electro-thermal mechanism of the inkjet printer.

16. The method according to claim 15, wherein the forming of the color photoresist bubbles comprises:
heating a color photoresist in a chamber of the inkjet printer such that pressure occurs in the chamber to expel color photoresist droplets from a nozzle of the inkjet printer, the droplets providing the color photoresist bubbles.

17. The method according to claim 12, further comprising performing a curing process in the inkjet printer before depositing the color photoresist bubbles.
